(19) United States
(12) Patent Application Publication
(10) Pub. No.: US 2026/0206126 A1
(43) Pub. Date: Jul. 16, 2026

(54) EMBEDDED VAPOR CHAMBER ASSEMBLY AND ELECTRONIC DEVICE

(71) Applicant: AAC Microtech (Changzhou) Co., Ltd., Changzhou City (CN)

(72) Inventors: Xiang Pan, Changzhou (CN); Shasha Xu, Changzhou (CN)

(21) Appl. No.: 19/336,462

(22) Filed: Sep. 22, 2025

Related U.S. Application Data
(63) Continuation of application No. PCT/CN2025/071759, filed on Jan. 10, 2025.

(51) Int. Cl. H05K 1/02

(52) U.S. Cl. CPC H05K 1/0204; H05K 2201/066

(57) ABSTRACT

Provided is an embedded vapor chamber assembly and electronic device. The embedded vapor chamber assembly includes circuit board, power chip, vapor chamber and heat sink. Circuit board is multi-layer circuit board, and includes first circuit board layer configured for attaching power chip, second circuit board layer serving as bottom plate, and third circuit board layer disposed between first circuit board layer and second circuit board layer. Vapor chamber is disposed between first circuit board layer and second circuit board layer, and projection of vapor chamber towards first circuit board layer covers power chip. Vapor chamber includes closed cavity, capillary structure and phase change liquid filled in cavity. Heat sink is attached to side of first circuit board layer, and at least fitted with part of surface of power chip. Compared with related art, heat dissipation performance of the provided embedded vapor chamber assembly is better.

### TECHNICAL FIELD

The present disclosure relates to the technical field of heat dissipation and, in particular, to an embedded vapor chamber assembly and an electronic device.

### BACKGROUND

With the development of electronic and electrical technologies and increasing demands of users, various electronic products in daily life, scientific research, and education have increasingly more functions and higher power, and heat generation of the electronic products is more and more serious. A vapor chamber (VC) is a lightweight and thin heat dissipation element. Due to its divergent vapor path and excellent 2D surface thermal conductivity, the vapor chamber can be applied to various electronic products to enhance the heat dissipation effect of the products, and therefore is currently an ideal solution to the heat dissipation problem of various electronic products.

In the vapor chamber solution in the prior art, the vapor chamber is generally arranged between a power chip and a metal housing of the product. After conducted to the vapor chamber, heat generated by the power chip is dissipated through the thermal conduction of the metal housing. However, the vapor chamber solution in the prior art relies on passive heat dissipation of the metal housing of the product, and an unavoidable gap caused by a packaging process is formed between the vapor chamber and the power chip, resulting in a poor heat dissipation effect.

Therefore, it is desirable to provide a new vapor chamber solution to solve the above problems.

### SUMMARY

The present disclosure aims to provide an embedded vapor chamber assembly with a better heat dissipation effect and an electronic device.

In order to solve the above technical problems, the present disclosure provides an embedded vapor chamber assembly, including a circuit board, a power chip, a vapor chamber and a heat sink. The circuit board is a multi-layer circuit board, and the circuit board includes a first circuit board layer configured for attaching the power chip, a second circuit board layer serving as a bottom plate, and a third circuit board layer disposed between the first circuit board layer and the second circuit board layer. The vapor chamber is disposed between the first circuit board layer and the second circuit board layer and is arranged in a same layer as the third circuit board layer, and an orthographic projection of the vapor chamber towards the first circuit board layer covers the power chip; the vapor chamber includes a closed cavity, a capillary structure arranged in the cavity and phase change liquid filled in the cavity. The heat sink is attached to a side of the first circuit board layer away from the third circuit board layer, and at least fitted with a part of a surface of the power chip.

As an improvement, at least one first through hole is provided in the first circuit board layer, at least one first protrusion structure is provided at a side of the vapor chamber close to the first circuit board layer, and the first protrusion structure passes through the first through hole so that the vapor chamber fits with the heat sink.

As an improvement, at least one second through hole is provided in the first circuit board layer, at least one second protrusion structure is provided at the side of the vapor chamber close to the first circuit board layer, and the second protrusion structure passes through the second through hole so that the vapor chamber fits with the power chip.

As an improvement, the third circuit board layer has a double-layer structure; the vapor chamber is embedded into the third circuit board layer, and fitted with the first circuit board layer and the second circuit board layer, respectively.

As an improvement, the embedded vapor chamber assembly further includes a fixing screw, a threaded hole is provided at a side of the heat sink fitting with the first circuit board layer, fixing holes are provided through the circuit board and the vapor chamber at positions corresponding to the threaded hole, respectively, and the fixing screw passes through the fixing holes along a direction from the third circuit board layer to the first circuit board layer to form a threaded connection with the threaded hole.

As an improvement, the heat sink is a finned heat sink.

As an improvement, the vapor chamber is made of copper, stainless steel or titanium alloy and is manufactured based on an electrochemical plating (ECP) process.

As an improvement, the vapor chamber is connected to a ground terminal on the first circuit board layer or the second circuit board layer.

As an improvement, a support structure fixedly supported on a plate body of the vapor chamber is further provided in the vapor chamber.

The present disclosure further provides an electronic device, including the embedded vapor chamber assembly described above.

Compared with the related art, the embedded vapor chamber assembly according to the present disclosure includes the circuit board, the power chip, the vapor chamber and the heat sink. The circuit board is the multi-layer circuit board, and the circuit board includes the first circuit board layer configured for attaching the power chip, the second circuit board layer serving as the bottom plate, and the third circuit board layer disposed between the first circuit board layer and the second circuit board layer. The vapor chamber is disposed between the first circuit board layer and the second circuit board layer and is arranged in the same layer as the third circuit board layer, and the orthographic projection of the vapor chamber towards the first circuit board layer covers the power chip. The vapor chamber includes the closed cavity, the capillary structure arranged in the cavity and the phase change liquid filled in the cavity. The heat sink is attached to the side of the first circuit board layer away from the third circuit board layer, and at least fitted with a part of the surface of the power chip. In the above structure, the vapor chamber is embedded into the multi-layer circuit board, and the thermal conductivity of the whole circuit board is improved through the embedded design. On the basis of integrating the vapor chamber, the heat sink is fitted with the power chip for auxiliary heat dissipation, which is more beneficial to directly controlling heat generation of the power chip on the circuit board. Compared with the related art, the heat dissipation performance of the embedded vapor chamber assembly according to the present disclosure is better.

### BRIEF DESCRIPTION OF DRAWINGS

To better describe the technical solutions in embodiments of the present disclosure, the following briefly describes the drawings required for the description of the embodiments. It is appreciated that the drawings in the following description show merely some embodiments of the present disclosure, and a person of ordinary skill in the art may still derive other drawings from these drawings without creative efforts. In the drawings:

FIG. 1 is a schematic perspective structural diagram of an embedded vapor chamber assembly according to an embodiment of the present disclosure;

FIG. 2 is a schematic overall exploded structural diagram of an embedded vapor chamber assembly according to an embodiment of the present disclosure; and

FIG. 3 is a sectional view taken along line A-A in the schematic perspective structural diagram of the embedded vapor chamber assembly of FIG. 1 according to an embodiment of the present disclosure.

### DESCRIPTION OF EMBODIMENTS

The technical solutions in the embodiments of the present disclosure are clearly and completely described with reference to the drawings in the embodiments of the present disclosure. It is appreciated that the described embodiments are not all but only a part of the embodiments of the present disclosure. All other embodiments obtained by a person of ordinary skill in the art based on the embodiments of the present disclosure without creative efforts shall fall within the protection scope of the present disclosure.

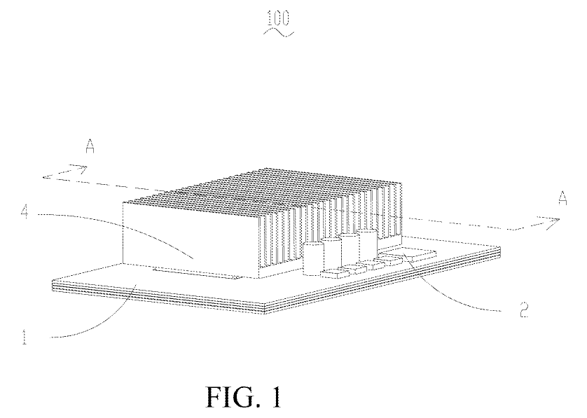

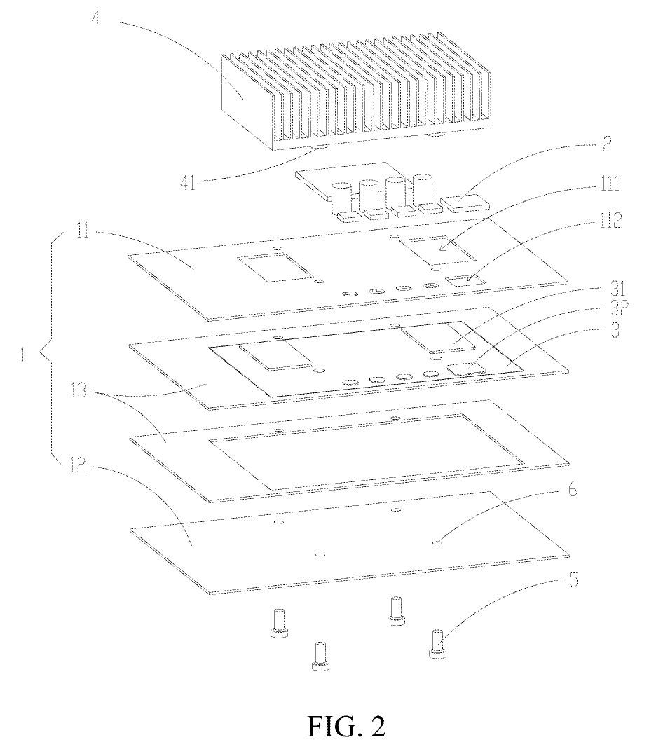

Referring to FIG. 1 to FIG. 3, an embodiment of the present disclosure provides an embedded vapor chamber assembly 100. FIG. 1 is a schematic perspective structural diagram of the embedded vapor chamber assembly according to the embodiment of the present disclosure, FIG. 2 is a schematic overall exploded structural diagram of the embedded vapor chamber assembly according to the embodiment of the present disclosure. The embedded vapor chamber assembly 100 includes a circuit board, a power chip 2, a vapor chamber 3 and a heat sink 4.

The circuit board 1 is a multi-layer circuit board, and the circuit board includes a first circuit board layer 11 configured for attaching the power chip 2, a second circuit board layer 12 serving as a bottom plate, and a third circuit board layer 13 disposed between the first circuit board layer 11 and the second circuit board layer 12.

The vapor chamber 3 is disposed between the first circuit board layer 11 and the second circuit board layer 12 and is arranged in the same layer as the third circuit board layer 13, and an orthographic projection of the vapor chamber 3 towards the first circuit board layer 11 covers the power chip 2.

The vapor chamber 3 includes a closed cavity, a capillary structure arranged in the cavity and phase change liquid filled in the cavity.

The heat sink 4 is attached to a side of the first circuit board layer 11 away from the third circuit board layer 13, and at least fitted with a part of a surface of the power chip 2.

The vapor chamber 3 covers the power chip 2 in terms of area to enable the heat generated by the power chip 2 to be transferred through the vapor chamber 3.

Specifically, in some embodiments of the present disclosure, in order to further improve the thermal conductivity of the vapor chamber 3, at least one first through hole 111 is provided in the first circuit board layer 11, at least one first protrusion structure 31 is provided at a side of the vapor chamber 3 close to the first circuit board layer 11, and the first protrusion structure 31 passes through the first through hole 111 so that the vapor chamber 3 fits with the heat sink 4. With such a design, the heat absorbed by the vapor chamber 3 from the circuit board can be transferred to the heat sink 4, and the heat sink 4 assists the vapor chamber 3 for auxiliary heat dissipation.

In some embodiments of the present disclosure, in order to further improve the heat dissipation performance of the vapor chamber 3 for the power chip 2, at least one second through hole 112 is provided in the first circuit board layer 11, at least one second protrusion structure 32 is provided at the side of the vapor chamber 3 close to the first circuit board layer 11, and the second protrusion structure 32 passes through the second through hole 112 so that the vapor chamber 3 fits with the power chip 2. With such a design, the vapor chamber 3 can not only transfer the heat generated by the power chip 2 through thermal conduction of the circuit board, but also directly transfer the heat by fitting with the power chip 2, thereby preventing the thermal conduction process from being impeded by the circuit board 1.

In conjunction with the design in which the vapor chamber 3 is fitted with the heat sink 4 in the above embodiment, the fitting between the vapor chamber 3 and the power chip 2 actually forms, between a bottom surface of the power chip 2 and the heat sink 4, a high-performance heat transfer channel based on the vapor chamber 3, thereby improving the overall heat dissipation performance of the assembly.

In some embodiments, the circuit board 1 is formed by fitting two double-layer circuit boards with the same structure. In this case, the third circuit board layer 13 has a double-layer structure, and the vapor chamber 3 is embedded into the third circuit board layer 13 and fitted with the first circuit board layer 11 and the second circuit board layer 12, respectively. With such a design, an fitting surface of the power chip 2 and the bottom plate of the entire circuit board can achieve balanced heat distribution through a large-area vapor chamber 3, thereby optimizing the heat dissipation performance of the circuit board.

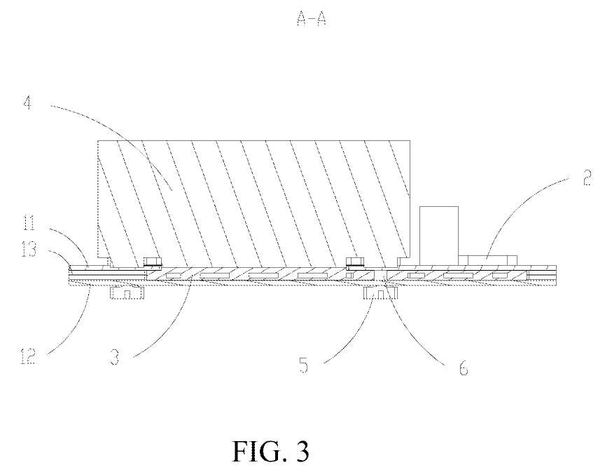

In some embodiments of the present disclosure, the heat sink 4 is a finned heat sink. In order to fix the heat sink 4, as shown in FIG. 3 which is a sectional view taken along line A-A in the schematic perspective structural diagram of the embedded vapor chamber assembly of FIG. 1 according to the embodiment of the present disclosure, the embedded vapor chamber assembly 100 further includes a fixing screw 5. A threaded hole 41 is provided at a side of the heat sink 4 fitting with the first circuit board layer 11, fixing holes 6 are provided through the circuit board 1 and the vapor chamber 3 at positions corresponding to the threaded hole 41, respectively, and the fixing screw 5 passes through the fixing holes 6 along a direction from the third circuit board layer 13 to the first circuit board layer 11 to form a threaded connection with the threaded hole 41.

In some embodiments of the present disclosure, the vapor chamber 3 is manufactured based on an electrochemical plating (ECP) process. The ECP process is a process for depositing metal copper on a semiconductor substrate by an electrochemical method. The vapor chamber 3 in the embodiment of the present disclosure can be manufactured by the ECP process with a high thermal conductivity material as a substrate. The substrate material may be copper, stainless steel, titanium alloy, or the like, all of which have good thermal conductivity.

In some embodiments, based on the structure of the embedded vapor chamber assembly 100 according to the embodiment of the present disclosure, the strength of the vapor chamber can be improved by designing a support structure on a plate body of the vapor chamber 3. The thermal conductivity of the vapor chamber 3 is further improved by connecting the vapor chamber 3 to a ground terminal on the circuit board layer.

An embodiment of the present disclosure further provides an electronic device, including the embedded vapor chamber assembly 100 according to the above embodiments. It can be understood that the electronic device designed based on the embedded vapor chamber assembly 100 according to the embodiments of the present disclosure can achieve a good heat dissipation performance based on the embedded design of the vapor chamber 3 of the embedded vapor chamber assembly 100 and the structure of the heat sink 4 for auxiliary heat dissipation. Reference is made to the description of the above embodiments for further details, which will not be repeated herein.

Compared with the related art, the embedded vapor chamber assembly according to the present disclosure includes the circuit board, the power chip, the vapor chamber and the heat sink. The circuit board is the multi-layer circuit board, and the circuit board includes the first circuit board layer configured for attaching the power chip, the second circuit board layer serving as the bottom plate, and the third circuit board layer disposed between the first circuit board layer and the second circuit board layer. The vapor chamber is disposed between the first circuit board layer and the second circuit board layer and is arranged in the same layer as the third circuit board layer, and the orthographic projection of the vapor chamber towards the first circuit board layer covers the power chip. The vapor chamber includes the closed cavity, the capillary structure arranged in the cavity and the phase change liquid filled in the cavity. The heat sink is attached to the side of the first circuit board layer away from the third circuit board layer, and at least fitted with a part of the surface of the power chip. In the above structure, the vapor chamber is embedded into the multi-layer circuit board, and the thermal conductivity of the whole circuit board is improved through the embedded design. On the basis of integrating the vapor chamber, the heat sink is fitted with the power chip for auxiliary heat dissipation, which is more beneficial to directly controlling heat generation of the power chip on the circuit board. Compared with the related art, the heat dissipation performance of the embedded vapor chamber assembly according to the present disclosure is better.

The above description is only embodiments of the present disclosure. It should be noted that improvements can be made by those of ordinary skill in the art without departing from the concept of the present disclosure, and all fall within the protection scope of the present disclosure.

What is claimed is:

1. An embedded vapor chamber assembly, comprising a circuit board, a power chip, a vapor chamber and a heat sink;
wherein the circuit board is a multi-layer circuit board, and the circuit board comprises a first circuit board layer configured for attaching the power chip, a second circuit board layer serving as a bottom plate, and a third circuit board layer disposed between the first circuit board layer and the second circuit board layer;
the vapor chamber is disposed between the first circuit board layer and the second circuit board layer and is arranged in a same layer as the third circuit board layer, and an orthographic projection of the vapor chamber towards the first circuit board layer covers the power chip; the vapor chamber comprises a closed cavity, a capillary structure arranged in the cavity and phase change liquid filled in the cavity; and
the heat sink is attached to a side of the first circuit board layer away from the third circuit board layer, and at least fitted with a part of a surface of the power chip.

2. The embedded vapor chamber assembly as described in claim 1, wherein at least one first through hole is provided in the first circuit board layer, at least one first protrusion structure is provided at a side of the vapor chamber close to the first circuit board layer, and the first protrusion structure passes through the first through hole so that the vapor chamber fits with the heat sink.

3. The embedded vapor chamber assembly as described in claim 1, wherein at least one second through hole is provided in the first circuit board layer, at least one second protrusion structure is provided at the side of the vapor chamber close to the first circuit board layer, and the second protrusion structure passes through the second through hole so that the vapor chamber fits with the power chip.

4. The embedded vapor chamber assembly as described in claim 1, wherein the third circuit board layer has a double-layer structure; the vapor chamber is embedded into the third circuit board layer, and fitted with the first circuit board layer and the second circuit board layer, respectively.

5. The embedded vapor chamber assembly as described in claim 1, further comprising a fixing screw, wherein a threaded hole is provided at a side of the heat sink fitting with the first circuit board layer, fixing holes are provided through the circuit board and the vapor chamber at positions corresponding to the threaded hole, respectively, and the fixing screw passes through the fixing holes along a direction from the third circuit board layer to the first circuit board layer to form a threaded connection with the threaded hole.

6. The embedded vapor chamber assembly as described in claim 1, wherein the heat sink is a finned heat sink.

7. The embedded vapor chamber assembly as described in claim 1, wherein the vapor chamber is made of copper, stainless steel or titanium alloy, and is manufactured based on an electrochemical plating (ECP) process.

8. The embedded vapor chamber assembly as described in claim 1, wherein the vapor chamber is connected to a ground terminal on the first circuit board layer or the second circuit board layer.

9. The embedded vapor chamber assembly as described in claim 1, wherein a support structure fixedly supported on a plate body of the vapor chamber is further provided in the vapor chamber.

10. An electronic device, comprising the embedded vapor chamber assembly as described in claim 1.
